(19) United States
(12) Patent Application Publication
(10) Pub. No.: US 2017/0200667 A1
(43) Pub. Date: Jul. 13, 2017

(54) Photopatternable Silicones For Wafer Level Z-Axis Thermal Interposer

(71) Applicant: Dow Corning Corporation, Midland, MI (US)

(72) Inventors: RANJITH SAMUEL JOHN, CUPERTINO, CA (US); HERMAN MEYNEN, LUBBEEK (BE); CRAIG R. YEAKLE, MIDLAND, MI (US)

(73) Assignee: Dow Corning Corporation, Midland, MI (US)

(21) Appl. No.: 15/316,622

(22) PCT Filed: May 29, 2015
(86) PCT No.: PCT/US15/33163

§ 371 Date: Dec. 6, 2016

Related U.S. Application Data
(60) Provisional application No. 62/014,242, filed on Jun. 19, 2014.

(51) Int. Cl. H01L 23/373; H01L 23/367; H01L 21/48; H01L 21/78; C09K 5/14; G03F 7/038; G03F 7/16; G03F 7/20; G03F 7/38; G03F 7/32; H01L 23/42; C08G 77/20

(52) U.S. Cl. CPC H01L 23/3737; H01L 23/42; H01L 23/3675; H01L 23/3736; H01L 21/4882; H01L 21/78; C08G 77/20; G03F 7/038; G03F 7/16; G03F 7/168; G03F 7/2002; G03F 7/38; G03F 7/32; C09K 5/14

(57) ABSTRACT

Methods for fabrication of thermal interposers, using a low stress photopatternable silicone are provided, for use in production of electronic products that feed into packaging of LEDs, logic and memory devices and other such semiconductor products where thermal management is desired. A photopatternable silicone composition, thermally conductive material and a low melting point compliant solder form a complete semiconductor package module. The photopatternable silicone is applied on a surface of a wafer and selectively radiated to form openings which provided user defined bondline thickness control. The openings are then filled with high conductivity pastes to form high conductivity thermal links. A low melting point curable solder is then applied where the solder wets the silicone as well as the thermally conductive path that leads to low thermal contact resistance between the structured z-axis thermal interposer and the heat sink and/or substrate which can be a wafer or PCB.

The present disclosure relates to photopatternable silicones and methods of forming interposers in semiconductor device packages using photopatternable silicone compositions.

Semiconductor devices are becoming smaller and more powerful. Semiconductor devices with high operating frequencies and large numbers of components with complex circuit densities are being fabricated with smaller packages, leading to increasing thermal challenges. High operating frequencies increase power consumption and consequently heat generation in a semiconductor device package. Typically, cooling hardware such as fans and heat sinks are used to dissipate the heat generated by the semiconductor device and cool the device. However, transfer of heat from the hot components in the semiconductor device package to the cooling hardware is may also be provided to significantly cool the semiconductor device.

Thermal Interface Materials (TIMs) are typically used as heat transport media between active semiconductor wafers/dies and substrates or heat sinks, to enhance the heat transport between the active die and heat sink. Gels, greases and adhesives filled with metal particles are used as TIMs for die to substrate, die to lid and/or die to heat sink attachment. Typical thermal conductivity values of the TIMs range from 1 to several Watts per meter-Kelvin (Wm⁻¹K⁻¹) depending on the filler type, size distribution, loading and starting matrix. General method of applying a TIM involves dispensing of the TIM material after the die is diced and bonded to an active die or substrate. The methods of applying TIMs are well known in the art. However, hitherto applications of TIMs take place on die levels, thereby limiting the use of TIMs. The term “die level” means that the application of TIM and assembly of the die happens after the processed wafer is diced into individual dies.

The TIM materials used for heat transport are made of insulative matrices such as epoxies or silicones which are filled with thermal conductive particles such as alumina, silver or gold for better thermal conduction. Thus the composite matrix of the filled TIM has a thermal conductivity closer to that of the insulative matrix rather than that of the fillers. For instance, the thermal conductivity of a typical silicone is 0.2-0.3 W m⁻¹K⁻¹, and when such a silicone is filled with silver particles whose thermal conductivity is 429 Wm⁻¹K⁻¹, the thermal conductivity of the silicone-silver composite is approximately 2-3 Wm⁻¹K⁻¹. Thus there is a general limitation on the effectiveness of TIMs as a heat transport medium.

Furthermore, the use of fillers in TIMs makes desirable careful management of the filler technology to prevent settling of fillers, as well as proper handling and dispensing of filled composites, forming uniform bond lines, and the like. These considerations further complicate the task of making a reliable low cost semiconductor device package module. Typically, the reverse side of most active semiconductor devices are rough, leading to air pockets and high thermal contact resistance between the TIM and the device thus reducing the effectiveness of the TIM.

Silicon interposers are being increasingly used as the heat transport medium within the semiconductor device package. Silicon interposers are typically passive silicon substrates or dies having through-silicon-vias that are used to interconnect active dies without the need to specifically design the dies for interface compatibility. Silicon interposers are used to stack active dies side-by-side and/or vertically in a package.

There have been endeavors to develop silicon interposers as heat transport mediums within the semiconductor device packages. For instance, U.S. patent application publication no. US20050280128 recites a thermal interposer provided for attachment to a surface of a semiconductor device. The interposer includes an upper plate and a lower plate hermetically bonded together. The use of two plates and the hermetic bonding of the two plates make the interposer complex to manufacture. Furthermore, precise bonding of the two plates is desired for efficient functioning of the interposer.

U.S. patent application publication no. US20060006526 mentions a multilayered thermal interposer having two conductors bonded to an insulating layer with a bonding layer. However, the multiple layers of the thermal interposer make the manufacturing of the interposer and the semiconductor device package more complex.

U.S. patent application publication no. US20100044856 mentions an electronic package having a die including a thermal interface material for conducting heat from the die, an organic substrate, and a thermal interposer provided between the organic substrate and the die. The area of the thermal interposer extends beyond a footprint of the die and includes the thermal interface material. The thermal interposer conducts heat generated by the die through the thermal interface material. However, to accommodate additional area of the thermal interposer that extends beyond the footprint of the die, a bigger semiconductor device package is desired, thus limiting the use of the thermal interposer and rendering the thermal interposer unusable when fabricating smaller packages.

U.S. patent publication no. US20120106117 suggests a silicon interposer having through-via interconnections for electrically connecting vertically/3D stacked electronic devices. The silicon interposer mentioned in US20120106117 is typically designed to electrically connect 3D stacked electronic devices.

WO2012/142592 recites a silicon interposer with through package vias. The silicon interposer comprises a silicon substrate in panel or wafer form having through package vias defined therein and redistribution layers on first and second sides of the silicon substrate simultaneously. However, the silicon interposer of WO2012/142592 is designed to reduce electrical losses within a semiconductor package thereby necessitating the use of a silicon wafer as the interposer. Moreover, the method of making the silicon interposer involves drilling or laser ablation of the wafer to create through package vias within the silicon wafer and further forming polymeric liners within the through package vias.

With the advent of 3-dimensional (3D) and 2.5D stacked memory and logic modules it is important to create architectures which are efficient mediums for thermal transport. Thus there is a need for newer more efficient methods of thermal management which allows for well controlled thin bond lines, low thermal contact resistances, high thermal conductivity and adaptability for large scale manufacturing.

### BRIEF SUMMARY OF THE INVENTION

The present disclosure is directed to methods of using a silicone composition to form thermally conductive interposers in semiconductor device packages for efficient thermal management. In accordance with an aspect of the present disclosure, there is provided a method of forming a thermally conductive interposer on a wafer. The method comprising filling a plurality of apertures in a cured layer formed on a surface of the wafer, with thermally conductive material to form the thermally conductive interposer on the wafer.

In accordance with another aspect of the present disclosure, there is provided a thermally conductive interposer for dissipating heat from a wafer. The interposer covers at least one surface of the wafer, the interposer is composed of a cured layer having a pattern of thermally conductive material disposed at discrete locations therein, wherein the cured layer is a product of photopatterning and curing a layer of a photopatternable silicone (PPS) composition comprising: (A) an organopolysiloxane containing an average of at least two silicon-bonded alkenyl groups per molecule, (B) an organosilicon compound containing an average of at least two silicon-bonded hydrogen atoms per molecule in a concentration sufficient to cure the composition, and (C) a catalytic amount of a photoactivated hydrosilylation catalyst. The interposer defines a plurality of apertures defined at pre-determined locations within the interposer, wherein at least some of the apertures have a thermally conductive material disposed therein.

In accordance with yet another aspect of the present disclosure, there is provided a method of preparing a semiconductor package. The method comprises filling a plurality of apertures in a cured layer formed on a surface of a wafer, with thermally conductive material to form a thermally conductive interposer on the wafer. The method further comprises depositing a layer of solder on the thermally conductive interposer. The method further comprises dicing the wafer to produce individual diced wafers with the thermally conductive interposer and the layer of solder formed thereon. The method further comprises placing each diced wafer in the proximity of a semiconductor package lid/heat sink such that the thermally conductive interposer of each diced wafer having the layer of solder thereon faces the heat sink and melting the solder to form a bond between thermally conductive material in the aperture and the heat sink.

In accordance with still another aspect of the present disclosure, there is provided a semiconductor package. The semiconductor package comprises a wafer comprising at least one surface; a thermally conductive interposer covering the surface of the wafer for dissipating heat from the wafer, wherein the interposer defines a plurality of apertures defined at pre-determined locations within the interposer, with at least some of the apertures having thermally conductive material disposed therein; a semiconductor package substrate; and a layer of solder dispensed between each filled aperture in the interposer and a semiconductor package lid/heat sink to form a bond between thermally conductive material in the aperture and the heat sink. The interposer is composed of a cured layer, wherein the cured layer is a product of photopatterning and curing a layer of a photopatternable silicone composition comprising: A) an organopolysiloxane containing an average of at least two silicon-bonded alkenyl groups per molecule, B) an organosilicon compound containing an average of at least two silicon-bonded hydrogen atoms per molecule in a concentration sufficient to cure the composition, and C) a catalytic amount of a photoactivated hydrosilylation catalyst.

### BRIEF DESCRIPTION OF THE ACCOMPANYING DRAWINGS

Various advantages of the invention will become apparent upon reading the following detailed description and upon reference to the accompanying drawings.

FIG. 1 shows a schematic representation of the packaged device with a photopatternable silicone composition based Z-axis thickness thermal interposer.

FIG. 2 shows a schematic representation of the process steps involved in the fabrication of an electronic package with a photopatternable silicone composition based Z-axis thickness thermal interposer at wafer level.

FIGS. 3a-3f show the microscopy images of the processed photopatternable silicone layer with conductive paste filled thermal apertures.

FIGS. 4a-4d show the microscopy images of the processed photopatternable silicone layer with metal deposited thermal apertures.

FIG. 5 shows a flow chart depicting the steps involved in the method of forming the thermally conductive interposer in accordance with additional exemplary embodiments.

While the invention is susceptible to various modifications and alternative forms, specific embodiments have been shown by way of example in the drawings and will be described in detail herein, and the invention is not intended to be limited to the particular forms disclosed.

### DETAILED DESCRIPTION OF THE INVENTION

As used herein, “may” confers a choice, not an imperative. “Optionally” means is absent, alternatively is present. “Contacting” means bringing into physical contact. “Operative contact” comprises functionally effective touching, e.g., as for modifying, coating, adhering, sealing, or filling. The operative contact may be direct physical touching, alternatively indirect touching. All U.S. patent application publications and patents referenced herein, or a portion thereof if only the portion is referenced, are hereby incorporated herein by reference to the extent that incorporated subject matter does not conflict with the present description, which would control in any such conflict. All states of matter are determined at 25° C. and 101.3 kPa unless indicated otherwise. All % are by weight unless otherwise noted. All wt % values are, unless otherwise noted, based on total weight of all ingredients used to synthesize or make the composition, which adds up to 100 wt %. Any Markush group comprising a genus and subgenus therein includes the subgenus in the genus, e.g., in “R is hydrocarbyl or alkenyl,” R may be alkenyl, alternatively R may be hydrocarbyl, which includes, among other subgenuses, alkenyl.

In accordance with an aspect of this invention a photopatternable silicone composition can be used to form a thermally conductive interposer on a wafer. Such use of a photopatternable silicone may enable end users to apply the silicone on semiconductor wafers as desired, pattern and develop/remove areas of the silicone wherein thermally conductive material is to be deposited, thus giving the users flexibility to design the location of the apertures closer to areas in need of higher heat dissipation. Furthermore, this aspect of the invention eliminates the need for the prior art filler technology mentioned earlier, thereby reducing the cost and complexity associated with filler management and homogeneously dispensing high viscosity filled TIMs. The aspect also provides good bond line thickness control and reduces the need for managing thermal contact resistance associated with filled TIMs. The term “bond lie” refers to the gap between the die and the heat sink which is defined by the thickness of the photopatternable silicone composition and the layer of solder applied onto the wafer.

The thermally conductive interposer may be formed at wafer level with thermal apertures/vias which may be of uniform thickness and/or width, alternatively of varying thickness and width thereby providing flexibility in design of via structures and locations and giving users the flexibility to locate the apertures at or close to “hot spots” on the die to dissipate heat from the die. The term “wafer level” means that the thermally conductive interposer is formed on a whole wafer before the wafer is diced into individual dies. Furthermore, this aspect can eliminate the need for handling and dispensing of thermal interface composite materials on the die level thus reducing the cost. Additionally, the photopatternable silicone acts as a stress buffer which enables the management of stress on active devices which are primarily composed of materials with different CTE (Coefficients of Thermal Expansion), thus helping to increase the reliability of the thermally conductive interposer and the devices.

The photopatternable silicone composition may be composed of three primary components and additional secondary components described in U.S. Pat. No. 7,517,808 which is hereby incorporated by reference. The primary components of photopatternable silicone composition include, (A) an organopolysiloxane containing an average of at least two silicon-bonded alkenyl groups per molecule, (B) an organosilicon compound containing an average of at least two silicon-bonded hydrogen atoms per molecule in a concentration sufficient to cure the composition, and (C) a catalytic amount of a photoactivated hydrosilylation catalyst.

Component (A) is at least one organopolysiloxane containing an average of at least two silicon-bonded alkenyl groups per molecule. The organopolysiloxane can have a linear, branched, or resinous structure. The organopolysiloxane can be a homopolymer or a copolymer. The alkenyl groups typically have from 2 to about 10 carbon atoms and are exemplified by, but not limited to, vinyl, allyl, butenyl, and hexenyl. The alkenyl groups in the organopolysiloxane may be located at terminal, pendant, or both terminal and pendant positions. The remaining silicon-bonded organic groups in the organopolysiloxane are independently selected from monovalent hydrocarbon and monovalent halogenated hydrocarbon groups free of aliphatic unsaturation. These monovalent groups typically have from 1 to about 20 carbon atoms, alternatively have from 1 to 10 carbon atoms, and are exemplified by, but not limited to alkyl such as methyl, ethyl, propyl, pentyl, octyl, undecyl, and octadecyl; cycloalkyl such as cyclohexyl; aryl such as phenyl, tolyl, xylyl, benzyl, and 2-phenylethyl; and halogenated hydrocarbon groups such as 3,3,3-trifluoropropyl, 3-chloropropyl, and dichlorophenyl. At least 50 percent, and alternatively at least 80%, of the organic groups free of aliphatic unsaturation in the organopolysiloxane can be methyl.

The viscosity of the organopolysiloxane at 25° C. is typically from 0.001 to 100,000 Pa·s, alternatively from 0.01 to 10,000 Pa·s, and alternatively from 0.01 to 1,000 Pa·s.

Examples of organopolysiloxanes useful as component (A) in the photopatternable silicone composition include, but are not limited to, polydiorganosiloxanes having the following formulae: ViMe₂SiO(Me₂SiO)ₐSiMe₂Vi, ViMe₂SiO(Me₂SiO)_{0.25a}(MePhSiO)_{0.75a}SiMe₂Vi, ViMe₂SiO(Me₂SiO)_{0.95a}(Ph₂SiO)_{0.05a}SiMe₂Vi, ViMe₂SiO(Me₂SiO)_{0.98a}(MeViSiO)_{0.02a}SiMe₂Vi, Me₃SiO(Me₂SiO)_{0.95a}(MeViSiO)_{0.05a}SiMe₃, and PhMeViSiO(Me₂SiO)ₐSiPhMeVi, where Me, Vi, and Ph denote methyl, vinyl, and phenyl respectively and a has a value such that the viscosity of the polydiorganosiloxane is from 0.001 to 100,000 Pa·s. at 25° C.

Methods of preparing organopolysiloxanes suitable for use in the photopatternable silicone composition, such as methods comprising hydrolysis and condensation of the corresponding organohalosilanes or equilibration of cyclic polydiorganosiloxanes, are well known in the art.

The organopolysiloxane of component (A) may be an organopolysiloxane resin. Examples of suitable organopolysiloxane resins include an MQ resin comprising R¹₃SiO_{1/2} units and SiO_{4/2} units, a TD resins comprising R¹SiO_{3/2} units and R¹₂SiO_{2/2} units, an MT resin comprising R¹₃SiO_{1/2} units and R¹SiO_{3/2} units, and an MTD resin comprising R¹₃SiO_{1/2} units, R¹SiO_{3/2} units, and R¹₂SiO_{2/2} units, wherein each R¹ is independently selected from monovalent hydrocarbon and monovalent halogenated hydrocarbon groups. The monovalent groups represented by R¹ typically have from 1 to about 20 carbon atoms and alternatively have from 1 to about 10 carbon atoms. Examples of monovalent groups include, but are not limited to, alkyl such as methyl, ethyl, propyl, pentyl, octyl, undecyl, and octadecyl; cycloalkyl such as cyclohexyl; alkenyl such as vinyl, allyl, butenyl, and hexenyl; aryl such as phenyl, tolyl, xylyl, benzyl, and 2-phenylethyl; and halogenated hydrocarbon groups such as 3,3,3-trifluoropropyl, 3-chloropropyl, and dichlorophenyl. At least one-third, and alternatively substantially all R¹ groups in the organopolysiloxane resin may be methyl. A typical organopolysiloxane resin may be an MQ resin, which comprises (CH₃)₃SiO_{1/2} siloxane units and SiO_{4/2} units, wherein the mole ratio of (CH₃)₃SiO_{1/2} units to SiO_{4/2} units is from 0.6 to 1.9.

The organopolysiloxane resin may contain an average of about 3 to 30 mole percent of alkenyl groups. The mole percent of alkenyl groups in the resin is defined here as the ratio of the number of moles of alkenyl-containing siloxane units in the resin to the total number of moles of siloxane units in the resin, multiplied by 100.

The organopolysiloxane resin can be obtained from commercial sources or can be prepared by methods well-known in the art. The resin may be prepared by treating a resin copolymer produced by the silica hydrosol capping process of Daudt et al. with at least an alkenyl-containing endblocking reagent. The method of Daudt et al. is disclosed in U.S. Pat. No. 2,676,182, which is hereby incorporated by reference to teach how to make organopolysiloxane resins suitable for use in the present invention.

Briefly stated, the method of Daudt et al. involves reacting a silica hydrosol under acidic conditions with a hydrolyzable triorganosilane such as trimethylchlorosilane, a siloxane such as hexamethyldisiloxane, or combinations thereof, and recovering a copolymer having M and Q units. The resulting copolymer product generally contains from about 2 to about 5 percent by weight of silicon-bonded hydroxyl groups (Si—OH groups).

A organopolysiloxane resin, which typically contains less than 2 percent by weight of silicon-bonded hydroxyl groups, can be prepared by reacting the copolymer product of Daudt et al. with an alkenyl-containing endblocking agent or a combination of an alkenyl-containing endblocking agent and an endblocking agent free of aliphatic unsaturation in an amount sufficient to provide from 3 to 30 mole percent of alkenyl groups and less than 2 percent by weight of silicon-bonded hydroxyl groups in the final organopolysiloxane resin. Examples of such endblocking agents include, but are not limited to, silazanes, siloxanes, and silanes. Suitable endblocking agents are known in the art and exemplified in U.S. Pat. No. 4,584,355 to Blizzard et al.; U.S. Pat. No. 4,591,622 to Blizzard et al.; and U.S. Pat. No. 4,585,836 to Homan et al.; which are hereby incorporated by reference. A single endblocking agent or a combination of such agents can be used to prepare the organopolysiloxane resin.

Component (A) can be a single organopolysiloxane or a combination comprising two or more organopolysiloxanes that differ in at least one of the following properties: structure, viscosity, average molecular weight, siloxane units, and sequence.

Component (B) is at least one organosilicon compound containing an average of at least two silicon-bonded hydrogen atoms per molecule. It is generally understood that crosslinking in the photopatternable silicone composition may occur when the sum of the average number of alkenyl groups per molecule in component (A) and the average number of silicon-bonded hydrogen atoms per molecule in component (B) is greater than four. The silicon-bonded hydrogen atoms in the organohydrogenpolysiloxane can be located at terminal, pendant, or at both terminal and pendant positions.

The organosilicon compound containing an average of at least two silicon-bonded hydrogen atoms per molecule can be an organosilane or an organohydrogensiloxane. The organosilane can be a monosilane, disilane, trisilane, or polysilane. Similarly, the organohydrogensiloxane can be a disiloxane, trisiloxane, or polysiloxane. The organosilicon compound may be the organohydrogensiloxane. The structure of the organosilicon compound can be linear, branched, cyclic, or resinous. At least 50 percent of the organic groups in the organosilicon compound may be methyl.

Examples of organosilanes suitable for use as component (B) include, but are not limited to, monosilanes such as diphenylsilane and 2-chloroethylsilane; disilanes such as 1,4-bis(dimethylsilyl)benzene, bis[(p-dimethylsilyl)phenyl]ether, and 1,4-dimethyldisilylethane; trisilanes such as 1,3,5-tris(dimethylsilyl)benzene and 1,3,5-trimethyl-1,3,5-trisilane; and polysilanes such as poly(methylsilylene)phenylene and poly(methylsilylene)methylene.

Examples of organohydrogensiloxanes suitable for use as component (B) include, but are not limited to, disiloxanes such as 1,1,3,3-tetramethyldisiloxane and 1,1,3,3-tetraphenyldisiloxane; trisiloxanes such as phenyltris(dimethylsiloxy)silane and 1,3,5-trimethylcyclotrisiloxane; and polysiloxanes such as a trimethylsiloxy-terminated poly(methylhydrogensiloxane), a trimethylsiloxy-terminated poly(dimethylsiloxane/methylhydrogensiloxane), a dimethylhydrogensiloxy-terminated poly(methylhydrogensiloxane), and a resin comprising H(CH₃)₂SiO_{1/2} units, (CH₃)₃SiO_{1/2} units, and SiO_{4/2} units.

Component (B) can be a single organosilicon compound containing an average of at least two silicon-bonded hydrogen atoms per molecule or a combination comprising two or more such compounds that differ in at least one of the following properties: structure, average molecular weight, viscosity, silane units, siloxane units, and sequence.

The concentration of component (B) in the photopatternable silicone composition is sufficient to cure, alternatively cure and crosslink, the composition. The exact amount of component (B) depends on the desired extent of cure, which generally increases as the ratio of the number of moles of silicon-bonded hydrogen atoms in component (B) to the number of moles of alkenyl groups in component (A) increases. Typically, the concentration of component (B) is sufficient to provide from 0.5 to 3 silicon-bonded hydrogen atoms per alkenyl group in component (A). The concentration of component (B) may be sufficient to provide from 0.7 to 1.2 silicon-bonded hydrogen atoms per alkenyl group in component (A).

Methods of preparing organosilicon compounds containing an average of at least two silicon-bonded hydrogen atoms per molecule are well known in the art. For example, organopolysilanes can be prepared by reaction of chlorosilanes in a hydrocarbon solvent in the presence of sodium or lithium metal (Wurtz reaction). Organopolysiloxanes can be prepared by hydrolysis and condensation of organohalosilanes.

To ensure compatibility of components (A) and (B), the predominant organic group in each component may be the same. This group may be methyl.

Component (C) is a photoactivated hydrosilylation catalyst. The photoactivated hydrosilylation catalyst can be any hydrosilylation catalyst capable of catalyzing the hydrosilylation of component (A) with component (B) upon exposure to radiation having a wavelength of 150 to 800 nm and subsequent heating. Component (C) may be a platinum group metal. Suitable platinum group metals include platinum, rhodium, ruthenium, palladium, osmium and iridium. The component (C) may be platinum, based on its high activity in hydrosilylation reactions. The suitability of particular photoactivated hydrosilylation catalyst for use in the photopatternable silicone composition can be readily determined by routine experimentation using the methods in the Examples section below.

Examples of suitable photoactivated hydrosilylation catalysts include, but are not limited to, platinum(II) β-diketonate complexes such as platinum(II) bis(2,4-pentanedioate), platinum(II) bis(2,4-hexanedioate), platinum(II) bis(2,4-heptanedioate), platinum(II) bis(1-phenyl-1,3-butanedioate, platinum(II) bis(1,3-diphenyl-1,3-propanedioate), platinum(II) bis(1,1,1,5,5,5-hexafluoro-2,4-pentanedioate); (η-cyclopentadienyl)trialkylplatinum complexes, such as (Cp)trimethylplatinum, (Cp)ethyldimethylplatinum, (Cp)triethylplatinum, (chloro-Cp)trimethylplatinum, and (trimethylsilyl-Cp)trimethylplatinum, where Cp represents cyclopentadienyl; triazene oxide-transition metal complexes, such as Pt[C₆H₅NNNOCH₃]₄, Pt[p-CN—C₆H₄NNNOC₆H₁₁]₄, Pt[p-H₃COC₆H₄NNNOC₆H₁₁]₄, Pt[p-CH₃(CH₂)ₓ—C₆H₄NNNOCH₃]₄, 1,5-cyclooctadiene.Pt[p-CN—C₆H₄NNNOC₆H₁₁]₂, 1,5-cyclooctadiene.Pt[p-CH₃O—C₆H₄NNNOCH₃]₂, [(C₆H₅)₃P]₃Rh[p-CN—C₆H₄NNNOC₆H₁₁], and Pd[p-CH₃(CH₂)ₓ—C₆H₄NNNOCH₃]₂, where x is 1, 3, 5, 11, or 17; (η-diolefin)(σ-aryl)platinum complexes, such as (η⁴-1,5-cyclooctadienyl)diphenylplatinum, η⁴-1,3,5,7-cyclooctatetraenyl)diphenylplatinum, (η⁴-2,5-norboradienyl)diphenylplatinum, (η⁴-1,5-cyclooctadienyl)bis-(4-dimethylaminophenyl)platinum, (η⁴-1,5-cyclooctadienyl)bis-(4-acetylphenyl)platinum, and (η⁴-1,5-cyclooctadienyl)bis-(4-trifluormethylphenyl)platinum. The photoactivated hydrosilylation catalyst may be a Pt(II) β-diketonate complex and alternatively the catalyst s platinum(II) bis(2,4-pentanedioate).

Component (C) can be a single photoactivated hydrosilylation catalyst or a combination comprising two or more such catalysts.

The concentration of component (C) in the photopatternable silicone composition is sufficient to catalyze the addition reaction of components (A) and (B) upon exposure to radiation and heat in the method described below. The concentration of component (C) is sufficient to provide typically from 0.1 to 1000 ppm of platinum group metal, alternatively from 0.5 to 100 ppm of platinum group metal, and alternatively from 1 to 25 ppm of platinum group metal, based on the combined weight of components (A), (B), and (C). The rate of cure typically is very slow below 1 ppm of platinum group metal. The use of more than 100 ppm of platinum group metal may result in no appreciable increase in cure rate, and is therefore uneconomical.

Methods of preparing the preceding photoactivated hydrosilylation catalysts of component (C) are well known in the art. For example, methods of preparing platinum(II) β-diketonates are reported by Guo et al. (Chemistry of Materials, 1998, 10, 531-536). Methods of preparing (η-cyclopentadienyl)trialkylplatinum complexes and are disclosed in U.S. Pat. No. 4,510,094. Methods of preparing triazene oxide-transition metal complexes are disclosed in U.S. Pat. No. 5,496,961. And, methods of preparing (η-diolefin)(σ-aryl)platinum complexes are disclosed in U.S. Pat. No. 4,530,879.

Combinations of the aforementioned components (A), (B), and (C) may begin to cure at ambient temperature, typically from 20° to 25° C. To obtain a longer working time or “pot life”, the activity of the catalyst under ambient conditions can be inhibited, retarded or suppressed by the addition of a suitable catalyst inhibitor to the component (C) of the photopatternable silicone composition. A catalyst inhibitor retards curing of the photopatternable silicone composition at ambient temperature, but does not prevent the composition from curing at elevated temperatures, typically from 30° to 150° C. Suitable catalyst inhibitors include various “ene-yne” systems such as 3-methyl-3-penten-1-yne and 3,5-dimethyl-3-hexen-1-yne; acetylenic alcohols such as 3,5-dimethyl-1-hexyn-3-ol, 1-ethynyl-1-cyclohexanol, and 2-phenyl-3-butyn-2-ol; maleates and fumarates, such as the well-known dialkyl, dialkenyl, and dialkoxyalkyl fumarates and maleates; and cyclovinylsiloxanes. Acetylenic alcohols constitute a typical class of catalyst inhibitors that may be used in the photopatternable silicone composition.

The concentration of the catalyst inhibitor in the photopatternable silicone composition can be sufficient to retard curing of the composition at ambient temperature without preventing or excessively prolonging cure at elevated temperatures. This concentration can vary widely depending on the particular inhibitor used, the nature and concentration of the hydrosilylation catalyst, and the nature of the organohydrogenpolysiloxane.

Catalyst inhibitor concentrations as low as one mole of inhibitor per mole of platinum group metal will in some instances yield a satisfactory storage stability and cure rate. In other instances, catalyst inhibitor concentrations of up to 500 or more moles of inhibitor per mole of platinum group metal may be desired. If desired, the optimum concentration for a particular catalyst inhibitor in a given photopatternable silicone composition can be readily determined by routine experimentation. Alternatively, the catalyst inhibitor may be used at a non-optimum concentration.

The photopatternable silicone composition can also comprise one or more additional ingredients, provided the additional ingredient(s) does/do not adversely affect the photopatterning or cure of the composition in the method. These additional ingredients are optional. Examples of additional ingredients include, but are not limited to, adhesion promoters, solvents (e.g., organic solvents), inorganic fillers, photosensitizers, and surfactants.

For example, the photopatternable silicone composition can further comprise a quantity of at least one organic solvent to lower the viscosity of the composition and facilitate the preparation, handling, and application of the composition. Examples of suitable solvents include, but are not limited to, saturated hydrocarbons having from 1 to about 20 carbon atoms; aromatic hydrocarbons such as xylenes and mesitylene; mineral spirits; halohydrocarbons; esters; ketones; silicone fluids such as linear, branched, and cyclic polydimethylsiloxanes; and combinations of such solvents. The optimum concentration of a particular organic solvent in the photopatternable silicone composition can be readily determined by routine experimentation. The organic solvent may be removed (e.g., by an evaporative method) from the photopatternable silicone composition before curing thereof.

The photopatternable silicone composition can be a one-part composition comprising components (A) through (C) in a single part or, alternatively, a multi-part composition comprising components (A) through (C) in two or more parts. In a multi-part composition, all of components (A), (B), and (C) are typically not present in the same part unless an inhibitor is also present. For example, a multi-part silicone composition can comprise a first part containing a portion of component (A) and a portion of component (B) and a second part containing the remaining portion of component (A) and all of component (C).

The one-part photopatternable silicone composition is typically prepared by combining components (A) through (C) and any optional additional ingredients in the desired proportions at ambient temperature with or without the aid of a solvent, which is described above. Although the order of addition of the various components is not critical if the silicone composition is to be used immediately, the hydrosilylation catalyst may be added last at a temperature below about 30° C. to prevent premature curing of the composition. Also, the multi-part silicone composition can be prepared by combining the particular components designated for each part, and then just prior to use the parts of the multi-part composition may be combined together.

A layer of the photopatternable silicone composition may be applied to a surface of a wafer, and the applied composition may be cured as described herein to give the cured layer. The cured layer is a product of photopatterning and curing a layer of a photopatternable silicone composition comprising components (A), (B) and (C). A plurality of apertures may be formed in the cured layer on the wafer. The plurality of apertures in the cured layer formed on the surface of the wafer may be filled with thermally conductive material to form a thermally conductive interposer on the wafer, wherein the thermally conductive interposer comprises a plurality of plugs of the thermally conductive material disposed in the apertures in a matrix comprising the cured layer defining the apertures. Typically, a mixture of the photopatternable silicone composition and a solvent is applied to the surface of the wafer to form an applied layer covering at least a portion of the surface of the wafer; photopatterning the applied layer; and curing the photopatterned applied layer. A portion of the applied layer is irradiated with radiation, including an i-line radiation, while another portion of the applied layer is masked, to produce a photopatterned layer, which is a partially irradiated layer having non-irradiated regions covering at least a portion of the surface of the wafer and irradiated regions covering the remainder of the surface of the wafer. The partially irradiated layer is then partially cured/baked by heat in what the art generally calls a “soft bake” step. The non-irradiated regions of the partially cured layer are then removed with a developing solvent to form a partially cured layer with a plurality of apertures defined therein. The partially cured layer is then cured to form a cured layer having a plurality of apertures therein. Typically, the thickness of the cured layer corresponds to a z-axis thickness and the apertures are formed through the cured layer along the z-axis thickness. As used herein, when referring to a material the term “layer” means a shape of the material that is restricted in one dimension, as for a coating, film or sheet. The dimension is typically referred to as thickness or height of the layer. The layer may define first and second major surfaces of the material that may be generally planar or contoured, e.g., as with a conformal coating topography having heights of up to a few micrometers. When referring to a layer, the phrase “along the z-axis thickness” means any direction through the height of the layer that is generally from any location at the first major surface of the layer to any location at the second major surface of the layer, or the vice versa direction. The direction of travel through the height of the layer may be graphically depicted as a ray through the thickness of the layer. The direction of travel includes rays having any angle relative to the first and second major surfaces of the layer, including right angles, which are (approximately) perpendicular to the first and second major surfaces, and acute and obtuse angles, which are non-perpendicular thereto. In some aspects at least some of the apertures are z-axis vias. The thermally conductive material may be inserted into the apertures in the cured layer to fill the apertures and give the thermally conductive interposer. In this aspect the thermally conductive interposer is prepared on the wafer by a type of process that may be referred to generally in the art as a “wafer level” process.

The wafer typically comprises semiconductor material including, but not limited to, silicon and gallium arsenide. The surface of the wafer comprises a plurality of integrated circuits including, but not limited to, DRAM, Flash memory, SRAM and Logic devices. The wafer further comprises dicing streets or scribe lines, along which the wafer can be sawed into individual wafers/chips to make semiconductor packages comprising individual wafers with the thermally conductive interposer formed thereon. Methods of fabricating integrated circuits and dicing (saw) streets on wafers are well known in the art. The semiconductor packages may be combined with additional elements such as a heat sink and/or a substrate to form semiconductor package devices.

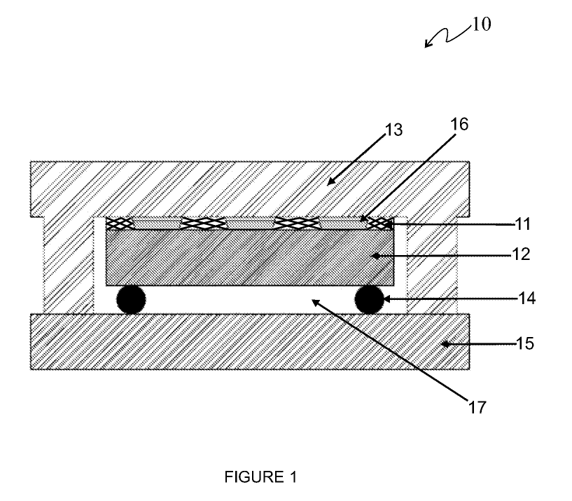

FIG. 1 shows a semiconductor packaged device (10) wherein the z-axis thermally conductive interposer (11) with the conductive material (16) therein, covering the wafer/chip (12), is the heat transport medium for transferring heat from the wafer (12) to the heat sink (13). The wafer/chip is bonded to a substrate (15) by a layer of solder (14) placed between the wafer (12) and the substrate (15) with air-gap (17) in the remainder of the space between the wafer (12) and the substrate (15).

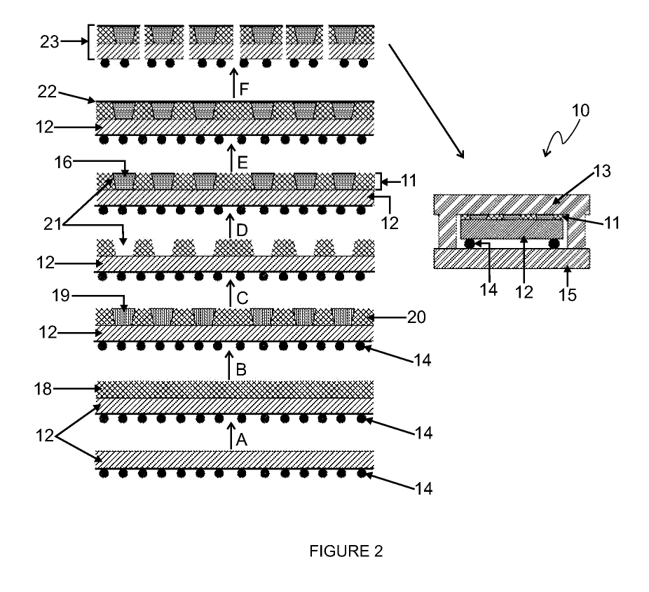

The aforementioned method of forming the thermally conductive interposer is carried out in accordance with an exemplary embodiment described herein below and shown in FIG. 2. In FIG. 2:
1) In a step A the photopatternable silicone (PPS) composition along with a solvent is deposited on a surface, typically a back surface or a front surface, of a wafer (12) by conventional coating methods such as spin coating, spray coating, doctor blading or draw bar coating to produce an applied layer (18) of thin film of thickness ranging from 5 μm to 50 μm with a thickness variation ≦2% depending on the wafer size. Additionally, solder balls (14) are dispensed at pre-determined locations on the surface of wafer not having the PPS composition deposited thereon, to enable the wafer to be electrically connected to a substrate (15). The applied layer is then heated on a hot plate or in an oven between 50 degrees Celsius (° C.) to 130° C. for 2 to 5 minutes to remove any excess solvent present in the applied layer. The heated wafer (12) is then cooled to room temperature.
2) In a step B a portion of the applied layer (18) is irradiated with radiation including an i-line radiation, wherein the intensity of Ultraviolet (UV) light is between 800 mJ/cm² to 2800 mJ/cm², but typically between 800 mJ/cm² to 1400 mJ/cm², to produce a partially irradiated layer having non-irradiated regions (19) which are soluble to solvents and cover at least a portion of the surface of the wafer (12) and irradiated regions (20) covering the remainder of the surface of the wafer (12) where cross linking is initiated. The UV radiated layer is then partially cured/baked by placing the layer on a hot plate or oven between 100° C. and 150° C. for 2 to 5 minutes to make the areas exposed to UV become substantially insoluble to developing solvent.
The term “substantially insoluble” means that the irradiated regions of the partially irradiated layer are not removed by dissolution in a developing solvent to the extent that the underlying surface of the wafer is irradiated. The term “soluble” means that the non-irradiated regions of the partially irradiated layer are removed by dissolution in a developing solvent, exposing the underlying surface of the wafer.
3) In a step C the wafer (12) is developed with developing solvents including, but not limited to, butyl acetate, mesitylene, and the like, by puddle, spray or immersion development for 2 to 5 minutes which removes the non-irradiated layer (19) thereby producing z-axis apertures/vias (21) with openings from 5 μm to 200 μm dependent on the bond line thickness. The solvent developed wafer (12) is then dried in the conventional spin-rinse-dryer system or a spin coater. The dried wafer is then placed in an oxygen oven for curing temperatures of 250° C. or less or in a nitrogen oven for curing temperatures ranging from 250° C. to 400° C. between 30 minutes to 3 hours.
4) In a step D the apertures/vias (21) are then filled with thermally conductive material (16) including, but not limited to, titanium, aluminum, nickel, copper or a combination thereof by conventional deposition methods such as evaporation or sputtering to form the z-axis thermally conductive interposer (11) on the wafer (12). The metal filled apertures provide paths of high thermal conductivity with well controlled bond line thickness to dissipate heat from the wafer.
5) In a step E a thin layer of low melting point solder (22) is then dispensed on the thermally conductive interposer for attaching a heat sink thereon. The solder is made from metals or their alloys including, but not limited to, indium, bismuth, indium-tin alloy, and the like.

The aforementioned exemplary embodiment is further extended to make a semiconductor package, wherein in FIG. 2,
6) in a step F the wafer (12) is then diced along the dicing (saw) streets to produce integrated circuit (IC) wafers/chips (23) having the thermally conductive interposer with z-axis thermal apertures/vias and the layer of solder thereon. The side having the thermally conductive interposer with the z-axis thermal apertures and the layer of solder is then placed facing a semiconductor package lid/heat sink or adjacent to another wafer/chip to which it needs to be attached. The solder is then melted in a conventional reflow oven or hot plate to form a bond between thermally conductive material in the z-axis thermal apertures and the heat sink (13) to give the semiconductor packaged device (10).

Additionally, the apertures/vias can be filled with a conductive paste including, but not limited to, silver, gold, or carbon paste by drop-on-demand process of an ink-jet printer as known by one skilled in the art. Furthermore, boron nitride and/or carbon nanotube pillars and the like, can also be placed in the apertures as thermal contacts.

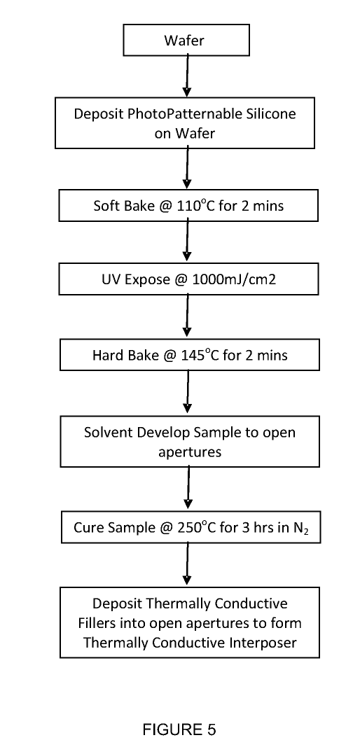

Additional exemplary embodiments of the method of forming the thermally conductive interposer on the semiconductor wafer are provided herein below to illustrate the invention to one skilled in the art and should not be interpreted as limiting the scope of the invention. FIG. 5 shows a flow chart depicting steps involved in the method of forming the thermally conductive interposer in accordance with the additional exemplary embodiments.

In FIG. 5, 1: Formation of Z-axis Silicone Vias on a Wafer is done using an aspect of the method comprising seven steps. A wafer (or other substrate) and a sample of a photopatternable silicone composition comprising a composition of vinyl functional silicone resin combined with a SiH functional polydimethyl siloxane and platinum catalyst are provided. In a first step of the method, the sample is deposited onto the wafer (or the other substrate) by spin coating at 2000 RPM (Revolutions per Minute) for 20 seconds to obtain a 10 micron thick film or layer with a uniformity of 2-3% across the wafer. In a second step, the coated wafer from the first step is then heated on a hot plate at 110° C. for 2 minutes in air. The second step is an example of a type of step that is generally referred to in the art as a “soft bake.” In a third step, the soft baked coated wafer from the second step is then placed on a UV exposure tool with a mask which allows for the patterning of the soft baked layer and eventually the location and creation of apertures or vias therein. The resulting masked coated wafer is then exposed to UV radiation with an exposure dose of 1000 mJ/cm². In a fourth step the UV exposed coated wafer from the third step is placed on a hot plate at 145° C. for 2 minutes. The fourth step is an example of a type of step that is generally referred to in the art as a “hard bake.” In a fifth step the hard baked coated wafer from the fourth step is then placed on a spin coater and butyl acetate as the developer solvent is dispensed on the hard baked coating. The resulting coated wafer is allowed to soak with the developer solvent for 2 minutes, and then is spin rinsed with butyl acetate and finally dried by spinning the resulting developed coated wafer at 2000 RPM for 30 seconds. The fifth step solvent develops the hard baked coated wafer, opening apertures such as vias in the coating. In a sixth step the developed coated wafer having apertures is then cured in a nitrogen oven at 250° C. for 3 hours to complete the curing of the developed coating. This results in a coated wafer with a patterned aperture (e.g., via) structure in/on the cured layer formed by curing a photopatternable silicone composition according to the method. In seventh step a thermally conductive filler is deposited into the apertures (e.g., vias) in the cured layer to fill the apertures (e.g., vias) and produce the thermal interposer layer on the wafer. An embodiment of the semiconductor package comprises the thermal interposer layer disposed on the wafer.

In an alternative aspect of the method, 2: Formation of Low Stress Thin Film Layers. A sample is prepared by spin coating a photopatternable silicone composition comprising a composition of vinyl functional silicone resin combined with a SiH functional polydimethyl siloxane and platinum catalyst. The sample is spin coated onto a wafer at 2000 RPM for 20 seconds to obtain a 40 micron thick film with a uniformity of 2-3% across the wafer. The sample is then heated on a hot plate at 110° C. for 2 minutes in air. The sample is then placed on a UV exposure tool and blanket exposed to UV radiation with an exposure dose of 1000 mJ/cm² to initiate polymerization across the entire film. The sample is then hard baked at 300° C. in a nitrogen oven to complete curing of the sample to a cured layer. The sample is then placed in a flexus chamber and thermal cycled between room temperature and 300° C. in the nitrogen environment with the stress measurement. The resulting measured stress as a result of the spin-on silicone is <2 MPa.

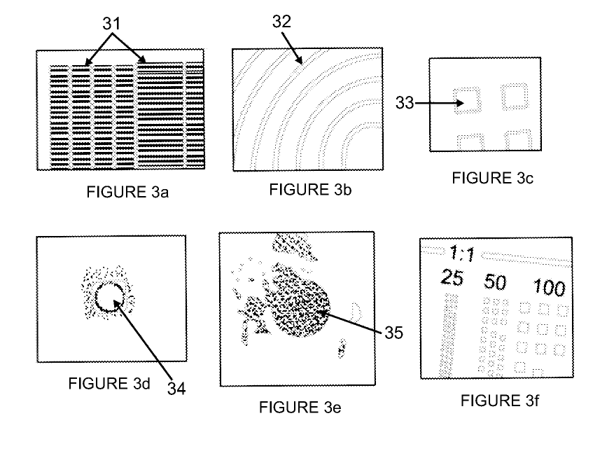

In an alternative aspect of the method, 3: Photopatternable silicone (PPS) with Thermally conductive Z-axis Silver Filled Vias. A sample is prepared by spin coating a photopatternable silicone composition comprising a composition of vinyl functional silicone resin combined with a SiH functional polydimethyl siloxane and platinum catalyst. The sample is spin coated onto a wafer at 2000 RPM (Revolutions per Minute) for 20 seconds to obtain a 10 micron thick film with a uniformity of 2-3% across the wafer. The sample is then heated on a hot plate at 110° C. for 2 minutes in air. The sample is then placed on a UV exposure tool with a mask which allows for the creation of vias. The sample is then exposed to UV radiation with an exposure dose of 1000 mJ/cm² and then placed on a hot plate at 145° C. for 2 minutes. The sample is then placed on a spin coater and butyl acetate is dispensed on the sample as the developer solvent. The sample is allowed to soak for 2 minutes and then spin rinsed with butyl acetate and finally dried by spinning the wafer at 2000 RPM for 30 seconds. The sample is then cured in a nitrogen oven at 250° C. for 3 hours to complete the curing of the sample to a cured layer. The vias were then filled with conductive silver paste which was dispensed by pipettes. The paste fills the vias successfully forming z-axis thermal vias. FIGS. 3a to 3f show microscopic images of the sample, wherein FIG. 3a shows the sample having 40 μm line spaces (31), FIG. 3b shows the sample having 50 μm line spaces (32), FIG. 3c shows the sample having 100 μm via (33), FIG. 3d shows the sample having 40 μm via (34), FIG. 3e shows the sample having silver filled z-axis vias (35), and FIG. 3f shows pattern analysis of the different vias in the sample.

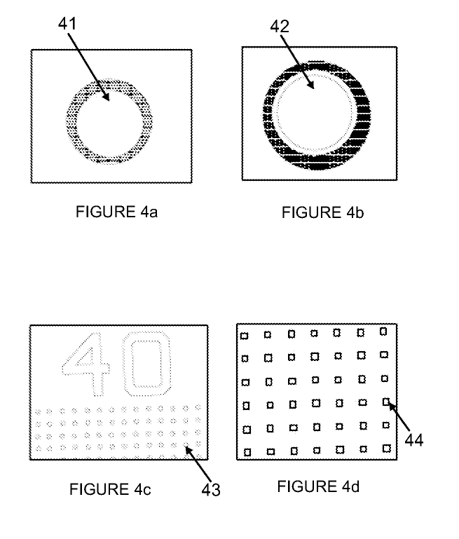

In an alternative aspect of the method, 4: Photopatternable silicone (PPS) with Thermally conductive Z-axis Titanium (Ti) & Aluminum (Al) Filled Vias. A sample is prepared by spin coating a photopatternable silicone composition comprising a composition of vinyl functional silicone resin combined with a SiH functional polydimethyl siloxane and platinum catalyst. The sample is spin coated onto a wafer at 2000 RPM for 20 seconds to obtain a 10 micron thick film with a uniformity of 2-3% across the wafer. The sample is then heated on a hot plate at 110° C. for 2 minutes in air. The sample is then placed on a UV exposure tool with a mask which allows for the creation of vias. The sample is then exposed to UV radiation with an exposure dose of 1000 mJ/cm² and then placed on a hot plate at 145° C. for 2 minutes. The sample is then placed on a spin coater and butyl acetate is dispensed on the sample as the developer solvent. The sample is allowed to soak for 2 minutes and then spin rinsed with butyl acetate and finally dried by spinning the wafer at 2000 RPM for 30 seconds. The sample is then cured in a nitrogen oven at 250° C. for 3 hours to complete the curing of the sample to a cured layer. The sample is then placed in a sputter chamber and Ti and Al are deposited to fill the vias. Furthermore, bumps are created by depositing Ti and Al on top of the silicone bumps. FIGS. 4a to 4d show microscopic images of the sample, wherein FIG. 4a shows the sample having 100 μm Ti and Al via (41), FIG. 4b shows the sample having 100 μm Ti via (42), FIG. 4c shows the sample having 40 μm Ti coated PPS bumps (43), and FIG. 4d shows the sample having 75 μm Ti and Al coated PPS bumps (44).

Invention embodiments include any one of the following numbered aspects.

Aspect 1. A method of forming a thermally conductive interposer on a wafer, the method comprising the step of filling a plurality of apertures in a cured layer formed on a surface of the wafer, with a thermally conductive material to form the thermally conductive interposer.

Aspect 2. The method of aspect 1, wherein the thickness of the cured layer corresponds to a z-axis thickness and the apertures are through the cured layer along the z-axis thickness.

Aspect 3. The method of aspect 2, wherein at least some of the apertures are z-axis vias.

Aspect 4. The method of aspect 3, wherein the maximum width (i.e., diameter) of each z-axis via is from 5 micrometers (μm) to 3 millimeters (mm), alternatively from 5 to <1 mm, alternatively from 5 μm to 200 μm.

Aspect 5. The method of any one of the aspects 1 to 4, wherein the cured layer is a product of photopatterning and curing a layer of a photopatternable silicone composition comprising: an organopolysiloxane containing an average of at least two silicon-bonded alkenyl groups per molecule, an organosilicon compound containing an average of at least two silicon-bonded hydrogen atoms per molecule in a concentration sufficient to cure the composition, and a catalytic amount of a photoactivated hydrosilylation catalyst.

Aspect 6. The method of aspect 5, which includes the step of applying a mixture of the photopatternable silicone composition and a solvent to at least one surface of the wafer to form an applied layer covering at least a portion of the surface of the wafer; photopatterning the applied layer; and curing the photopatterned applied layer.

Aspect 7. The method of aspect 6, wherein the photopatternable silicone composition is applied by a coating method selected from the group consisting of spin coating, spray coating, doctor blading and draw bar coating.

Aspect 8. The method of any one of the aspects 6 and 7, which includes the steps of: irradiating a portion of the applied layer with a radiation including an i-line radiation, while masking another portion of the applied layer, to produce a partially-irradiated layer having non-irradiated regions covering at least a portion of the surface of the wafer and irradiated regions covering the remainder of the surface of the wafer; partially curing the irradiated applied layer by heat; removing the non-irradiated regions of the partially cured layer with a developing solvent to form a partially cured layer with a plurality of z-axis apertures defined therein; and curing the partially cured layer to give the cured layer. The “irradiated applied layer” means the layer after the applying and irradiating steps and before the partially curing step.

Aspect 9. The method of aspect 8, wherein the radiation is ultraviolet (UV) radiation and intensity of the UV radiation is in the range from 800 millijoules per square centimeter (mJ/cm²) to 2800 mJ/cm².

Aspect 10. The method as aspect in aspect 8, wherein the irradiated applied layer is partially cured by heating the layer to a temperature in the range from 100° C. to 150° C. for from 2 minutes to 5 minutes.

Aspect 11. The method of aspect 8, wherein the step of removing the non-irradiated regions is carried out by immersing the partially cured layer in the developing solvent selected from the group consisting of butyl acetate and mesitylene.

Aspect 12. The method of aspect 8, wherein the partially cured layer is cured by heating the partially cured layer to a temperature in the range from 180° C. to 400° C., alternatively from 200° C. to 400° C., alternatively from 250° C. to 400° C., for from 30 minutes to 3 hours. As the temperature increases, the environment or atmosphere in which the partially cured layer is heated may be made to be increasingly pure or inert (e.g., the atmosphere may be air at 180° C. or 200° C. and an argon or helium at 400° C.

Aspect 13. The method of aspect 6, further comprising, after the step of applying the photopatternable silicone composition, the step of removing at least a portion of the solvent from the applied layer by heating the applied layer to a temperature in the range from 50° C. to 130° C. for 2 minutes to 5 minutes.

Aspect 14. The method of aspect 5, wherein the organopolysiloxane is an organopolysiloxane resin comprising R¹₃SiO^{1/2} siloxane units and SiO_{{4/2}} siloxane units wherein each R¹ is independently selected from monovalent hydrocarbon and monovalent halogenated hydrocarbon groups, and the mole ratio of R¹₃SiO_{1/2} units to SiO_{{4/2}} units in the organopolysiloxane resin is from 0.6 to 1.9; wherein the organosilicon compound is an organohydrogenpolysiloxane; wherein the photoactivated hydrosilylation catalyst is a platinum(II) β-diketonate; or wherein the organopolysiloxane is an organopolysiloxane resin comprising R¹₃SiO^{1/2} siloxane units and SiO_{{4/2}} siloxane units wherein each R¹ is independently selected from monovalent hydrocarbon and monovalent halogenated hydrocarbon groups, and the mole ratio of R¹₃SiO_{1/2} units to SiO_{{4/2}} units in the organopolysiloxane resin is from 0.6 to 1.9, the organosilicon compound is an organohydrogenpolysiloxane, and the photoactivated hydrosilylation catalyst is a platinum(II) β-diketonate.

Aspect 15. The method of aspect 1, wherein the thickness of the cured layer is from 5 μm to 50 μm.

Aspect 16. The method of aspect 1, wherein the thermally conductive material is selected from the group consisting of titanium; aluminum; nickel; copper; silver; gold; alloys of any two or more of titanium, aluminum, nickel, copper, silver, and gold; carbon, boron nitride; carbon nanotubes; and combinations of any two or more thereof.

Aspect 17. The method of aspect 1, wherein the wafer defines a plurality of dicing streets.

Aspect 18. A thermally conductive interposer for dissipating heat from a wafer, the interposer covering at least one surface of the wafer, the interposer is composed of a cured layer having a pattern of a thermally conductive material disposed at discrete locations therein, wherein the cured layer is a product of photopatterning and curing a layer of a photopatternable silicone composition comprising: an organopolysiloxane containing an average of at least two silicon-bonded alkenyl groups per molecule, an organosilicon compound containing an average of at least two silicon-bonded hydrogen atoms per molecule in a concentration sufficient to cure the composition, and a catalytic amount of a photoactivated hydrosilylation catalyst; the interposer defining a plurality of apertures at pre-determined locations within the interposer, wherein at least some of the apertures having the thermally conductive material disposed therein.

Aspect 19. The interposer of aspect 18, wherein the thickness of the cured layer corresponds to a z-axis thickness and the apertures are through the cured layer along the z-axis thickness.

Aspect 20. The interposer of aspect 19, wherein at least some of the apertures are z-axis vias.

Aspect 21. A method of making a semiconductor package, the method comprising the following steps: Filling, with thermally conductive material a plurality of apertures in a cured layer formed on a surface of a wafer, to form a thermally conductive interposer on the wafer; dicing the wafer to produce individual diced wafers with the thermally conductive interposer formed thereon; placing each diced wafer in the proximity of a substrate such that the thermally conductive interposer of each diced wafer faces the substrate; placing a bead or layer of solder between each filled aperture in the interposer and the substrate; and melting the solder to form a bond between thermally conductive material in the aperture and the substrate.

Aspect 22. The method of aspect 21, wherein the thickness of the cured layer corresponds to a z-axis thickness and the apertures are through the cured layer along the z-axis thickness.

Aspect 23. The method of aspect 22, wherein at least some of the apertures are z-axis vias.

Aspect 24. The method of any one of the aspects 21 to 23, wherein the cured layer is a product of photopatterning and curing a layer of a photopatternable silicone composition comprising: an organopolysiloxane containing an average of at least two silicon-bonded alkenyl groups per molecule, an organosilicon compound containing an average of at least two silicon-bonded hydrogen atoms per molecule in a concentration sufficient to cure the composition, and a catalytic amount of a photoactivated hydrosilylation catalyst.

Aspect 25. The method of aspect 24, which includes the step of applying the photopatternable silicone composition along with a solvent to at least one surface of the wafer to form an applied layer covering at least a portion of the surface of the wafer.

Aspect 26. The method of aspect 25, wherein the photopatternable silicone composition is applied by a coating method selected from the group consisting of spin coating, spray coating, doctor blading and draw bar coating.

Aspect 27. The method of any one of the aspects 25 and 26, which includes the steps of: irradiating a portion of the applied layer with a radiation including an i-line radiation, while masking another portion of the applied layer, to produce a partially-irradiated layer having non-irradiated regions covering at least a portion of the surface of the wafer and irradiated regions covering the remainder of the surface of the wafer; partially curing the irradiated applied layer by heat; removing the non-irradiated regions of the partially cured layer with a developing solvent to form a partially cured layer with a plurality of z-axis apertures defined therein; and curing the partially cured layer to give the cured layer.

Aspect 28. The method of aspect 21, wherein the substrate is selected from the group consisting of a semiconductor package substrate, a semiconductor package lid and another wafer.

Aspect 29. The method of aspect 21, wherein the solder is selected from the group consisting of indium, bismuth, indium-tin alloy, indium-bismuth alloy and indium-bismuth-tin alloy.

Aspect 30. A semiconductor package comprising: a wafer comprising at least one surface; a thermally conductive interposer covering the surface of the wafer for dissipating heat from the wafer, the interposer defining a plurality of apertures defined at pre-determined locations within the interposer, at least some of the apertures having thermally conductive material disposed therein, the interposer composed of a cured layer, wherein the cured layer is a product of photopatterning and curing a layer of a photopatternable silicone composition comprising: an organopolysiloxane containing an average of at least two silicon-bonded alkenyl groups per molecule, an organosilicon compound containing an average of at least two silicon-bonded hydrogen atoms per molecule in a concentration sufficient to cure the composition, and a catalytic amount of a photoactivated hydrosilylation catalyst; a semiconductor package substrate; and a bead or layer of solder dispensed between each filled aperture in the interposer and the substrate to form a bond between thermally conductive material in the aperture and the substrate.

Aspect 31. The semiconductor package of aspect 30, wherein the thickness of the cured layer corresponds to a z-axis thickness and the apertures are through the cured layer along the z-axis thickness.

Aspect 32. The semiconductor package of aspect 31, wherein at least some of the apertures are z-axis vias.

Throughout this disclosure, the word “comprise”, and variations such as “comprises” or “comprising”, are open-ended and will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the different embodiments of the invention, and may achieve one or more of the desired objects or results.

Any discussion of documents, acts, materials, devices, articles or the like that has been included in this specification is solely for the purpose of providing a context for the invention. It is not to be taken as an admission that any or all of these matters form part of the prior art base or were common general knowledge in the field relevant to the invention as it existed anywhere before the priority date of this application.

The numerical values mentioned for the various physical parameters, dimensions or quantities are only approximations and it is envisaged that the values higher/lower than the numerical values assigned to the parameters, dimensions or quantities fall within the scope of the invention, unless there is a statement in the specification specific to the contrary.

Wherever a range of values is specified, a value up to 10%, alternatively up to 5%, alternatively up to 1% below and above the lowest and highest numerical value respectively, of the specified range, is included in the scope of the disclosure.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while embodiments herein have been described, those skilled in the art will recognize that the embodiments herein can be practiced with modification within the spirit and scope of the embodiments as described herein.

1) A method of forming a thermally conductive interposer on a wafer, the method comprising the step of filling a plurality of apertures in a cured layer formed on a surface of the wafer, with a thermally conductive material to form the thermally conductive interposer.

2) The method of claim 1, wherein the thickness of the cured layer corresponds to a z-axis thickness and the apertures are through the cured layer along the z-axis thickness.

3) The method of claim 1, wherein the cured layer is a product of photopatterning and curing a layer of a photopatternable silicone composition comprising:
A) an organopolysiloxane containing an average of at least two silicon-bonded alkenyl groups per molecule,
B) an organosilicon compound containing an average of at least two silicon-bonded hydrogen atoms per molecule in a concentration sufficient to cure the composition, and
C) a catalytic amount of a photoactivated hydrosilylation catalyst.

4) The method of claim 3, which includes the step of applying a mixture of the photopatternable silicone composition and a solvent to at least one surface of the wafer to form an applied layer covering at least a portion of the surface of the wafer; photopatterning the applied layer; and curing the photopatterned applied layer.

5) The method of claim 4, which includes the steps of:
i) irradiating a portion of the applied layer with a radiation including an i-line radiation, while masking another portion of the applied layer, to produce a partially-irradiated layer having non-irradiated regions covering at least a portion of the surface of the wafer and irradiated regions covering the remainder of the surface of the wafer;
ii) partially curing the irradiated applied layer by heat;
iii) removing the non-irradiated regions of the partially cured layer with a developing solvent to form a partially cured layer with a plurality of z-axis apertures defined therein; and
iv) curing the partially cured layer to give the cured layer.

6) The method of claim 5,
wherein the radiation is ultraviolet (UV) radiation and intensity of the UV radiation is in the range from 800 millijoules per square centimeter (mJ/cm²) to 2800 mJ/cm²; or
wherein the irradiated applied layer is partially cured by heating the layer to a temperature in the range from 100 degrees Celsius (° C.) to 150° C. for from 2 minutes to 5 minutes; or
wherein the step of removing the non-irradiated regions is carried out by immersing the partially cured layer in the developing solvent selected from the group consisting of butyl acetate and mesitylene; or
wherein the partially cured layer is cured by heating the partially cured layer to a temperature in the range from 180 degrees Celsius (° C.) to 400° C. for from 30 minutes to 3 hours.

7) The method of claim 4, further comprising, after the step of applying the photopatternable silicone composition, the step of removing at least a portion of the solvent from the applied layer by heating the applied layer to a temperature in the range from 50 degrees Celsius (° C.) to 130° C. for 2 minutes to 5 minutes.

8) The method of claim 1, wherein the thermally conductive material is selected from the group consisting of titanium; aluminum; nickel; copper; silver; gold; alloys of any two or more of titanium, aluminum, nickel, copper, silver, and gold; carbon, boron nitride; carbon nanotubes; and combinations of any two or more thereof.

9) A thermally conductive interposer for dissipating heat from a wafer, the interposer covering at least one surface of the wafer, the interposer is composed of a cured layer having a pattern of a thermally conductive material disposed at discrete locations therein, wherein the cured layer is a product of photopatterning and curing a layer of a photopatternable silicone composition comprising:
A) an organopolysiloxane containing an average of at least two silicon-bonded alkenyl groups per molecule,
B) an organosilicon compound containing an average of at least two silicon-bonded hydrogen atoms per molecule in a concentration sufficient to cure the composition, and
C) a catalytic amount of a photoactivated hydrosilylation catalyst;
the interposer defining a plurality of apertures at pre-determined locations within the interposer, wherein at least some of the apertures having the thermally conductive material disposed therein.

10) A thermally conductive interposer as prepared by the method of claim 1.

11) The thermally conductive interposer of claim 10, wherein at least some of the apertures are z-axis vias.

12) A method of making a semiconductor package, the method comprising the following steps:
i) Filling, with thermally conductive material a plurality of apertures in a cured layer formed on a surface of a wafer, to form a thermally conductive interposer on the wafer;
ii) dicing the wafer to produce individual diced wafers with the thermally conductive interposer formed thereon;
iii) placing each diced wafer in the proximity of a substrate such that the thermally conductive interposer of each diced wafer faces the substrate;
iv) placing a bead or layer of solder between each filled aperture in the interposer and the substrate; and
v) melting the solder to form a bond between thermally conductive material in the aperture and the substrate.

13) The method of claim 12, wherein the thickness of the cured layer corresponds to a z-axis thickness and the apertures are through the cured layer along the z-axis thickness.

14) The method of claim 12, wherein the cured layer is a product of photopatterning and curing a layer of a photopatternable silicone composition comprising:
A) an organopolysiloxane containing an average of at least two silicon-bonded alkenyl groups per molecule,
B) an organosilicon compound containing an average of at least two silicon-bonded hydrogen atoms per molecule in a concentration sufficient to cure the composition, and
C) a catalytic amount of a photoactivated hydrosilylation catalyst.

15) A semiconductor package comprising:
i) a wafer comprising at least one surface;
ii) a thermally conductive interposer covering the surface of the wafer for dissipating heat from the wafer, the interposer defining a plurality of apertures defined at pre-determined locations within the interposer, at least some of the apertures having thermally conductive material disposed therein, the interposer composed of a cured layer, wherein the cured layer is a product of photopatterning and curing a layer of a photopatternable silicone composition comprising:
A) an organopolysiloxane containing an average of at least two silicon-bonded alkenyl groups per molecule,
B) an organosilicon compound containing an average of at least two silicon-bonded hydrogen atoms per molecule in a concentration sufficient to cure the composition, and
C) a catalytic amount of a photoactivated hydrosilylation catalyst;
iii) a semiconductor package substrate; and
iv) a bead or layer of solder dispensed between each filled aperture in the interposer and the substrate to form a bond between thermally conductive material in the aperture and the substrate.
